(19) United States
(12) Patent Application Publication
(10) Pub. No.: US 2007/0105292 A1
(43) Pub. Date: May 10, 2007

(54) Method for fabricating high tensile stress film and strained-silicon transistors

(76) Inventors: Neng-Kuo Chen, Hsin-Chu City (TW); Teng-Chun Tsai, Hsin-Chu City (TW); Hsiu-Lien Liao, Tai-Chung City (TW); Chien-Chung Huang, Tai-Chung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/163,988

(22) Filed: Nov. 7, 2005

(51) Int. Cl. H01L 21/8234; H01L 21/336

(52) U.S. Cl. 438/197

(57) ABSTRACT

A method for fabricating high tensile stress film and strained-silicon transistors. First, a semiconductor substrate is provided and a gate, at least a spacer, and a source/drain region are formed on the semiconductor substrate. Next, n deposition processes are performed to form n layers of high tensile stress film over the surface of the gate and the source/drain region, in which each high tensile stress film is treated with a heat treatment process and n is greater than or equal to two.

### BACKGROUND OF THE INVENTION

1. Field of the Invention

The invention relates to a method for fabricating high tensile stress film, and more particularly, to a method for forming high tensile stress film on a strained-silicon transistor.

2. Description of the Prior Art

As semiconductor technology advances and development of integrated circuits revolutionizes, the computing power and storage capacity for computers also increase exponentially, which further increases the expansion of related industries. As predicted by Moore Law, the number of transistors utilized in integrated circuits has been doubled every 18 months and semiconductor processes also have advanced from 0.18 micron in 1999, 0.13 micron in 2001, 90 nanometer (0.09 micron) in 2003, to 65 nanometer (0.065 micron) in 2005.

As the semiconductor processes advance, how to increase the driving current for metal oxide semiconductor (MOS) transistors for fabrication processes under 65 nanometer has become an important topic. According to this trend, the utilization of high tensile stress films for increasing the driving current of MOS transistors has become increasingly popular.

Currently, the utilization of high tensile stress films to increase the driving current of MOS transistors is divided into two categories: one being a poly stressor formed before the formation of nickel silicides and the other being a contact etch stop layer (CESL) formed after the formation of the nickel silicides. In general, the thermal budget for the fabrication of poly stressors can be greater than 1000° C. However, due to intolerability to overly high temperature of the nickel silicides, the thermal budget for the fabrication of contact etch stop layer should be maintained below 430° C. Preferably, the fabrication of the high tensile stress films involves first depositing a film composed of silicon nitride (SiN) followed by a UV curing process to increase the stress of the film and at the same time increase the driving current of the MOS transistor.

Please refer to FIG. 1 through FIG. 3. FIG. 1 through FIG. 3 are perspective diagrams showing the means of fabricating a strained-silicon NMOS transistor according to the prior art. As shown in FIG. 1, a semiconductor substrate 10 is provided and a gate structure 12 is formed on the semiconductor substrate 10, in which the gate structure 12 includes a gate oxide layer 14, a gate 16 disposed on the gate oxide layer 14, a cap layer 16 disposed on the gate 16, and an oxide-nitride-oxide (ONO) offset spacer 20. Preferably, the gate oxide layer 14 is composed of silicon dioxide, the gate 16 is composed of doped polysilicon, and the cap layer 18 is composed of silicon nitride to protect the gate 16. Additionally, a shallow trench isolation (STI) 22 is formed around the active area of the gate structure 21 within the semiconductor substrate 10.

As shown in FIG. 2, an ion implantation process is performed to form a source/drain region 26 in the semiconductor substrate 10 around the spacer 20. Next, a rapid thermal annealing (RTA) process is performed to activate the dopants within the source/drain region 26 and repair the damage of the lattice structure of the semiconductor substrate 10 resulting from the ion implantation process.

As shown in FIG. 3, a high tensile stress film 28 composed of silicon nitride or silicon oxide is disposed over the surface of the gate structure 12 and the source/drain region 26. Subsequently, a curing process is performed to cure the high tensile stress film 28 disposed on the gate structure 12 and the source/drain region 26. Preferably, the curing process is able to increase the stress of the high tensile stress film 28 by expanding the semiconductor substrate 10 underneath the gate 16, such as the lattice arrangement in the channel region, thereby increasing the electron mobility in the channel region and the driving current of the strained-silicon NMOS transistor.

However, as the UV curing process often utilizes photons to break the Si—H and SiN—H bond of the silicon nitride to increase stress of the film, the efficiency will be unavoidably limited by the depth of the film. In other words, high tensile stress film with greater depth will exhibit a lower stress. By performing only a single deposition process to form a layer of high tensile stress film and performing one UV curing process on the high tensile stress film, the efficiency of the UV curing process according to the conventional method of fabricating high tensile stress film will be affected when the depth of the film is overly large, thereby influencing the driving current of the MOS transistors. Hence, how to effectively increase the stress of the high tensile stress film has become an important task.

### SUMMARY OF THE INVENTION

It is therefore an objective of the present invention to provide a method for utilizing heat treatment on MOS transistors to solve the above-mentioned problem.

According to the present invention, a method for fabricating strained-silicon transistors includes providing a semiconductor substrate and forming a gate, at least a spacer, and a source/drain region on the semiconductor substrate; and performing n deposition processes to form n layers of high tensile stress film over the surface of the gate and the source/drain region, wherein each high tensile stress film is treated with a heat treatment process and n is greater than or equal to two.

In contrast to the conventional method of fabricating high tensile stress films, the present invention divides the conventional method of just utilizing one deposition process to form a single high tensile stress film and performing one UV curing process on the film into performing multiple deposition processes and multiple heat treatment processes, thereby effectively increasing the stress of the high tensile stress film and the driving current of the NMOS transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 3 are perspective diagrams showing the means of fabricating a strained-silicon NMOS transistor according to the prior art.

FIG. 4 through FIG. 7 are perspective diagrams showing the means of fabricating a strained-silicon NMOS transistor according to the present invention.

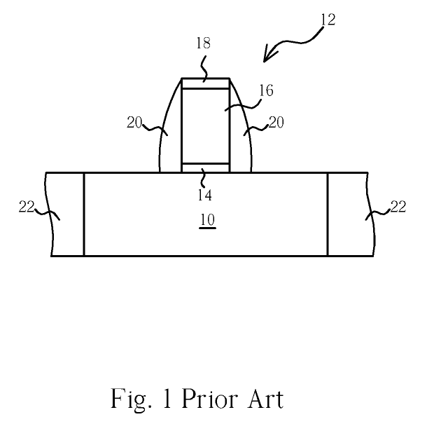

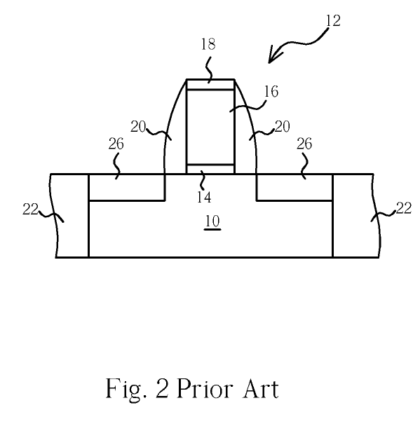

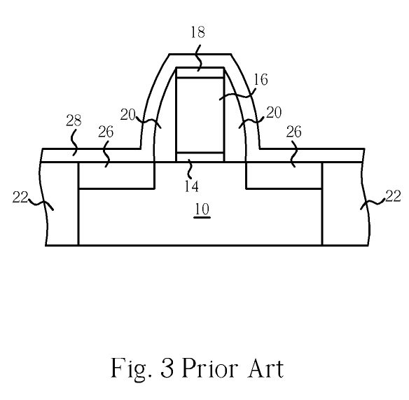

### DETAILED DESCRIPTION

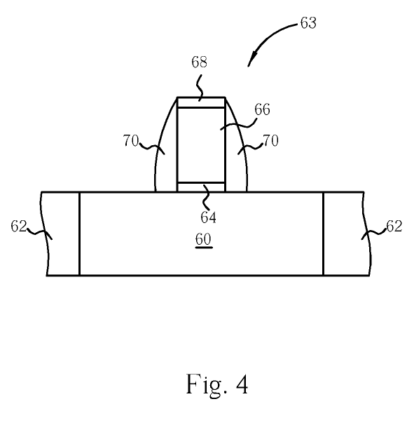

Please refer to FIG. 4 through FIG. 7. FIG. 4 through FIG. 7 are perspective diagrams showing the means of fabricating a strained-silicon PMOS transistor according to the present invention. As shown in FIG. 4, a semiconductor substrate 60, such as a silicon wafer or a silicon-on-insulator (SOI) substrate, is provided and a gate structure 63 is formed on the semiconductor substrate 60, in which the gate structure 63 includes a gate dielectric 64, a gate 66 disposed on the gate dielectric 64, a cap layer 68 formed on the gate 66, and an ONO offset spacer 70. Preferably, the gate dielectric 64 is composed of silicon dioxide via oxidation or deposition processes, the gate 66 is composed of doped polysilicon, and the cap layer 68 is composed of silicon nitride for protecting the gate 66 or polycide. Additionally, a shallow trench isolation (STI) 62 is formed around the active area of the gate structure 63 within the semiconductor substrate 60.

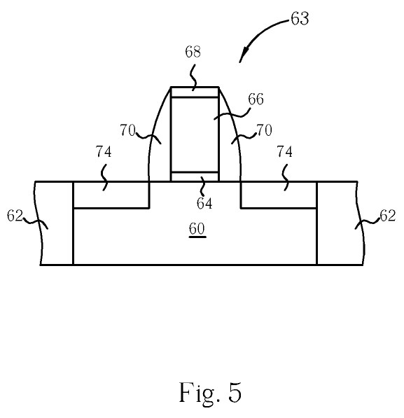

As shown in FIG. 5, an ion implantation process is performed to form a source/drain region 74 in the semiconductor substrate 60 surrounding the gate structure 63. Next, a rapid thermal annealing process is performed to use a temperature between 900° C. to 1050° C. to activate the dopants within the source/drain region 74, and at the same time repair the damage of the lattice structure of the semiconductor substrate 60 surface resulting from the ion implantation process. Additionally, depending on different product demands and fabrication processes, a lightly doped drain (LDD) or a source/drain extension can be formed between the source/drain region 74 and the gate structure 63.

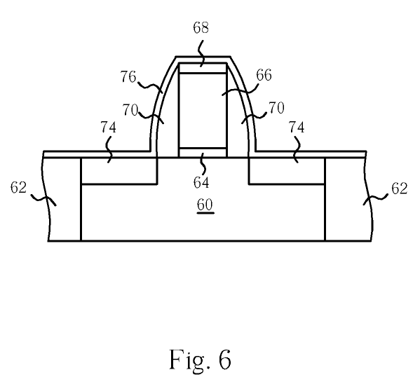

As shown in FIG. 6, a deposition process is performed to form a high tensile stress film 76 with depth between 100 angstroms and 1000 angstroms over the surface of the gate structure 63 and the source/drain region 74. Preferably, the high tensile stress film 76 is composed of silicon nitride or silicon oxide, and under present equipment and fabrication processes, the tensile stress status of the as-deposition of silicon nitride is approximately between 0.2 GPa to 1.5 GPa. Next, an in-situ or a non in-situ heat treatment including a UV curing process, an anneal process, such as a thermal spike anneal process, or an e-beam treatment, is performed on the high tensile stress film 76 to increase the stress of the high tensile stress film 76 and at the same time expand the semiconductor substrate 60 underneath the gate structure 63, such as the lattice arrangement in the channel region, thereby increasing the electron mobility in the channel region and the driving current of the strained silicon NMOS transistor.

According to the preferred embodiment of the present invention, the UV curing process is performed by utilizing an integrated equipment (not shown), in which the temperature of the UV curing process is between 30 seconds to 50 minutes and the ultraviolet wavelength of the UV curing process is between 100 nm to 400 nm. Additionally, if thermal spike anneal process were utilized on the high tensile stress film 76, the temperature of the thermal spike anneal according to the preferred embodiment of the present invention is between 200° C. to 1000° C., and the length of the thermal spike anneal process is between 0 to 120 seconds.

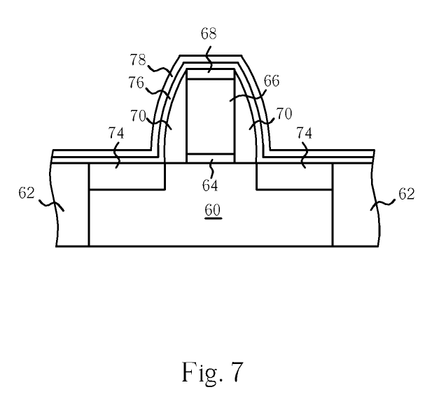

As shown in FIG. 7, another deposition process is repeated to form another high tensile stress film 78 with depth between 100 angstroms and 1000 angstroms on the high tensile stress film 76. Next, a similar heat treatment process, such as another UV curing process, thermal spike anneal process, or e-beam treatment is performed on the high tensile stress film 78 to increase the stress of the high tensile stress film 78.

Preferably, the deposition process performed for forming the high tensile stress film and the heat treatment process utilized on the high tensile stress film according to the present invention should be performed at least two times or more. In other words, after a deposition process is performed to form a high tensile stress film, a heat treatment process is utilized subsequently on the film. Ideally, the deposition process and the heat treatment process will be performed repeatedly until a desired depth of the film is reached. For instance, if a high tensile stress film with a final depth of 1000 angstroms were to be formed, the conventional method will deposit a silicon nitride (SiN) high tensile stress film with a depth of 1000 angstroms directly and perform a UV curing process on the high tensile stress film, such that the tensile stress status of the SiN film will be approximately 1.4 GPa and the ion gain of the NMOS transistor will be 73 μA/μm. By utilizing the present invention of performing the deposition process at least two times and utilizing a heat treatment process on the high tensile stress film formed from each deposition process, the total tensile stress status of the SiN film will be increased to 1.62 GPa or above and the ion gain of the driving current for the NMOS transistor will be increased to 105 μA/μm. According to the result from experiment utilizing the present invention, the method of fabricating a tensile stress film with equal depth for NMOS transistors is able to increase the ion gain percentage by approximately 26%.

By dividing the conventional method of just utilizing one deposition process to form a high tensile stress film and performing one UV curing process on the film into multiple deposition processes and multiple heat treatment processes, the present invention is able to greatly increase the stress of the high tensile stress film by increasing the total tensile stress status of the film to approximately 0.5 GPa to 2.5 GPa, thereby increasing the driving current of the NMOS transistor.

In addition to the fabrication process described above, the UV curing process and the thermal spike anneal process of the present invention can also be utilized alternately while performing the heat treatment process on the high tensile stress film. For instance, after the high tensile stress film 76 with depth between 100 angstroms to 1000 angstroms is formed over the surface of the gate structure 63 and the source/drain region 74, an UV curing process is performed on the high tensile stress film 76. Subsequently, after another high tensile stress film 78 is formed on the high tensile stress film 76, a thermal spike anneal process is performed to increase the stress of the high tensile stress film 76 and 78. By performing different heat treatment process alternately, the users are able to freely control the stress of the high tensile stress film according to different fabrication processes, product demands, and equipments.

Depending on different fabrication processes and product demands, the high tensile stress film 76 and 78 can also serve as a contact etch stop layer (CESL) to block the etching process while forming contact holes. For instance, after the formation of the high tensile stress film 76 and 78, an inter-layer dielectric (ILD) (not shown) can be formed over the surface of the high tensile stress film 78. Next, an anisotropic etching process is performed by utilizing a patterned photoresist (not shown) as etching mask to form a plurality of contact holes (not shown) in the inter-layer dielectric, in which the contact holes will serve as a connecting bridge to other electronic devices.

In contrast to the conventional method of fabricating high tensile stress films, the present invention divides the conventional method of just utilizing one deposition process to form a single high tensile stress film and performing one UV curing process on the film into performing multiple deposition processes and multiple heat treatment processes, thereby effectively increasing the stress of the high tensile stress film and the driving current of the NMOS transistor. Additionally, the present invention can also be applied to other processes including the fabrication of a poly stressor, a contact etch stop layer (CESL), or other applications requiring the utilization of high tensile stress film.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating high tensile stress film comprising:
performing n deposition processes to form n layers of high tensile stress film over the surface of a substrate, wherein each high tensile stress film is treated with a heat treatment process and n is greater than or equal to two.

2. The method of claim 1, wherein the high tensile stress film comprises silicon nitride (SiN) or silicon oxide (SiO).

3. The method of claim 2, wherein the tensile stress status of the as-deposition of each silicon nitride film is between 0.2 GPa to 1.5 GPa.

4. The method of claim 3, wherein the total tensile stress status of the high tensile stress film after performing the heat treatment process on each high tensile stress film is between 0.5 GPa to 2.5 GPa.

5. The method of claim 1, wherein the depth of each high tensile stress film is between 100 angstroms to 1000 angstroms.

6. The method of claim 1, wherein the heat treatment process comprises an UV curing, an anneal process or an e-beam treatment.

7. The method of claim 6, wherein the anneal process comprises a thermal spike anneal process.

8. The method of claim 6, wherein the temperature of the UV curing process is between 150° C. to 700° C.

9. The method of claim 6, wherein the length of the UV curing process is between 30 seconds to 60 minutes.

10. The method of claim 6, wherein the ultraviolet wavelength of the UV curing process is between 100 nm to 400 nm.

11. The method of claim 6, wherein the temperature of the thermal spike anneal process is between 200° C. to 1000° C.

12. The method of claim 6, wherein the length of the thermal spike anneal process is between 0 to 120 seconds.

13. The method of claim 1, wherein the heat treatment process comprises an in-situ or a non in-situ process.

14. A method for fabricating strained-silicon transistors comprising:
providing a semiconductor substrate and forming a gate, at least a spacer, and a source/drain region on the semiconductor substrate; and
performing n deposition processes to form n layers of high tensile stress film over the surface of the gate and the source/drain region, wherein each high tensile stress film is treated with a heat treatment process and n is greater than or equal to two.

15. The method of claim 14, wherein the semiconductor substrate is a wafer or a silicon-on-insulator (SOI) substrate.

16. The method of claim 14, wherein the strained-silicon transistor comprises a gate dielectric formed between the gate and the semiconductor substrate.

17. The method of claim 14, wherein the high tensile stress film comprises silicon nitride (SiN) or silicon oxide (SiO).

18. The method of claim 14, wherein the tensile stress status of the as-deposition of each silicon nitride film is between 0.2 GPa to 1.5 GPa.

19. The method of claim 18, wherein the total tensile stress status of the high tensile stress film after performing the heat treatment process on each high tensile stress film is between 0.5 GPa to 2.5 GPa.

20. The method of claim 14, wherein the depth of each high tensile stress film is between 100 angstroms to 1000 angstroms.

21. The method of claim 14, wherein the heat treatment process comprises an UV curing, an anneal process, or an e-beam treatment.

22. The method of claim 21, wherein the anneal process comprises a thermal spike anneal process.

23. The method of claim 21, wherein the temperature of the UV curing process is between 150° C. to 700° C.

24. The method of claim 21, wherein the length of the UV curing process is between 30 seconds to 60 minutes.

25. The method of claim 21, wherein the ultraviolet wavelength of the UV curing process is between 100 nm to 400 nm.

26. The method of claim 21, wherein the temperature of the thermal spike anneal process is between 200° C. to 1000° C.

27. The method of claim 21, wherein the length of the thermal spike anneal process is between 0 to 120 seconds.

28. The method of claim 14, wherein the heat treatment process comprises an in-situ or non in-situ process.

29. The method of claim 14, wherein the strained-silicon transistors comprise NMOS transistors.
